(19) United States
(12) Patent Application Publication
(10) Pub. No.: US 2026/0129759 A1
(43) Pub. Date: May 7, 2026

(54) ELECTRONIC COMPONENT MODULE

(71) Applicant: Murata Manufacturing Co., Ltd., Kyoto-fu (JP)

(72) Inventor: Shun IMAI, Nagaokakyo-shi (JP)

(73) Assignee: Murata Manufacturing Co., Ltd., Kyoto-fu (JP)

(21) Appl. No.: 19/379,113

(22) Filed: Nov. 4, 2025

(30) Foreign Application Priority Data
Nov. 5, 2024 (JP) 2024-193805

(51) Int. Cl. H05K 1/14; H05K 1/02

(52) U.S. Cl. CPC H05K 1/147; H05K 1/0218

(57) ABSTRACT

An electronic component module includes: a rigid board; a plurality of electronic components mounted on the rigid board; and a bendable flexible substrate mounted on the rigid board. The flexible substrate is mounted on the rigid board, passing between the plurality of electronic components. The flexible substrate includes a wiring line for transmitting a signal, and a first ground layer. The first ground layer is electrically connected to a reference potential of the rigid board.

### CROSS-REFERENCE TO RELATED APPLICATION

This application claims benefit of priority to Japanese Patent Application No. 2024-193805, filed Nov. 5, 2024, the entire content of which is incorporated herein by reference.

### BACKGROUND

### Technical Field

The present disclosure relates to an electronic component module.

### Background Art

An electronic component module includes a substrate having a surface on which a wiring line is provided, and a plurality of electronic components mounted on the surface of the substrate. Further, an electronic component module disclosed in International Publication No. 2018/151134 includes a circuit board and an electrical element arranged so as to straddle electronic components mounted on the circuit board.

### SUMMARY

The electronic component module disclosed in International Publication No. 2018/151134 has room for improvement with respect to the suppression of signal interference between the components mounted on the circuit board.

In view of the above, the present disclosure provides an electronic component module capable of suppressing signal interference between the components mounted on a circuit board.

An electronic component module according to the present disclosure includes a rigid board; a plurality of electronic components mounted on the rigid board; and a flexible substrate that is bendable and mounted on the rigid board. When viewing one main surface of the rigid board in plan, the flexible substrate is mounted on the rigid board, passing between the plurality of electronic components mounted on the rigid board. The flexible substrate includes a wiring line for transmitting a signal, and a first ground layer. The first ground layer is electrically connected to a reference potential of the rigid board.

According to the present disclosure, signal interference between the components mounted on a circuit board can be suppressed.

### BRIEF DESCRIPTION OF THE DRAWINGS

FIG. 1 is a perspective view illustrating an electronic component module according to a first embodiment;

FIG. 2 is a perspective view illustrating a configuration of a multilayer wiring board before a flexible substrate is mounted in FIG. 1;

FIG. 3 is a view illustrating a configuration of the flexible substrate according to the first embodiment;

FIG. 4 is an enlarged view illustrating a portion of the flexible substrate illustrated in FIG. 3;

FIG. 5 is a view illustrating the flexible substrate in a state of being bent along bending lines;

FIG. 6 is a view illustrating a cross-section of a portion of the flexible substrate illustrated in FIG. 5;

FIG. 7 is a view for explaining the structure of a short portion of the flexible substrate illustrated in FIG. 5;

FIG. 8 is a view for explaining the structure of the short portion of the flexible substrate illustrated in FIG. 5;

FIG. 9 is a view illustrating a configuration of a main portion of a flexible substrate used in an electronic component module according to a second embodiment;

FIG. 10 is a view illustrating a configuration of the main portion of the flexible substrate used in the electronic component module according to the second embodiment;

FIG. 11 is a view illustrating a configuration of the main portion of the flexible substrate used in the electronic component module according to the second embodiment;

FIG. 12 is a view illustrating a first example of a structure in which a surface mount device is mounted using the flexible substrate according to the second embodiment;

FIG. 13 is a view illustrating a cross-section of a portion of the flexible substrate illustrated in FIG. 12;

FIG. 14 is a view illustrating a second example of a structure in which a surface mount device is mounted using the flexible substrate according to the second embodiment;

FIG. 15 is a view illustrating a cross-section of a portion of the flexible substrate illustrated in FIG. 14;

FIG. 16 is a sectional view illustrating a configuration of a flexible substrate according to a modification of the second embodiment;

FIG. 17 is a view illustrating a configuration of a main portion of a flexible substrate used in an electronic component module according to a third embodiment;

FIG. 18 is a view illustrating the flexible substrate in a state of being bent along respective bending lines;

FIG. 19 is a perspective view illustrating the electronic component module according to the third embodiment;

FIG. 20 is a view illustrating a state in which the electronic component module is filled with a resin;

FIG. 21 is a view illustrating a configuration of a main portion of a flexible substrate used in an electronic component module according to a fourth embodiment;

FIG. 22 is a view illustrating the flexible substrate in a state of being bent along respective bending lines;

FIG. 23 is a perspective view illustrating a configuration example of a ground substrate;

FIG. 24 is a view illustrating a state in which the flexible substrate and the ground substrate are provided on the multilayer wiring board;

FIG. 25 is a view illustrating a state in which a resin is filled in the state illustrated in FIG. 24; and

FIG. 26 is a view illustrating an example of a connection substrate.

### DETAILED DESCRIPTION

Hereinafter, embodiments of the present disclosure will be described in detail with reference to the accompanying drawings. In the following description of each embodiment, components that are the same or equivalent to those of other embodiments are denoted by the same reference signs, and the description thereof will be simplified or omitted. The present disclosure is not limited by each embodiment. The components of each embodiment include those that can be easily replaced by a person skilled in the art, or those that are substantially identical. The configurations described below can be combined as appropriate. The configurations can be omitted, replaced, or changed within the scope of the disclosure. In the second and subsequent embodiments, descriptions of matters common to the first embodiment will be omitted as appropriate, and only differences will be described. In particular, similar effects of similar configurations will not be repeatedly described for each embodiment.

### First Embodiment

### Configuration

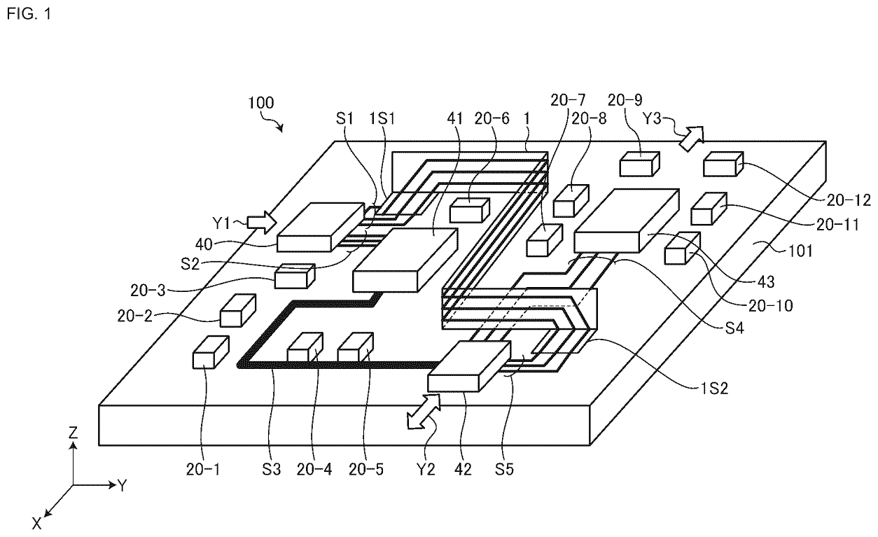

FIG. 1 is a perspective view illustrating an electronic component module 100 according to a first embodiment. In FIG. 1, the electronic component module 100 includes a multilayer wiring board 101 and a flexible substrate 1. The multilayer wiring board 101 is a rigid board that cannot be bent. The flexible substrate 1 is a substrate that can be bent.

Here, in FIG. 1, the direction from the back side to the front side of the multilayer wiring board 101 is defined as an X-axis direction, the direction from the left side to the right side of the multilayer wiring board 101 is defined as a Y-axis direction, and the direction from the lower side to the upper side of the multilayer wiring board 101 is defined as a Z-axis direction. The Z-axis direction is the thickness direction of the multilayer wiring board 101. In the drawings to be referred to in the following description, the direction from the back side to the front side of the multilayer wiring board 101 may be referred to as a positive direction or a positive side of the X-axis, the direction from the front side to the back side of the multilayer wiring board 101 may be referred to as a negative direction or a negative side of the X-axis, the direction from the left side to the right side of the multilayer wiring board 101 may be referred to as a positive direction or a positive side of the Y-axis, the direction from the right side to the left side of the multilayer wiring board 101 may be referred to as a negative direction or a negative side of the Y-axis, the direction from the lower side to the upper side of the multilayer wiring board 101 may be referred to as a positive direction or a positive side of the Z-axis, and the direction from the upper side to the lower side of the multilayer wiring board 101 may be referred to as a negative direction or a negative side of the Z-axis.

As illustrated in FIG. 1, signal lines S1 to S5 for transmitting signals are provided on the surface of the multilayer wiring board 101. Further, although not illustrated in the drawings, the multilayer wiring board 101 has wiring layer(s) inside the board.

As illustrated in FIG. 1, electronic components, which are a control integrated circuit (IC) 40, a power amplifier IC 41, an antenna switch 42, and a low-noise amplifier IC 43, are mounted on one main surface of the multilayer wiring board 101. Other electronic components 20-1 to 20-12 are mounted on the main surface of the multilayer wiring board 101. In other words, the multilayer wiring board 101 is a rigid board on which a plurality of electronic components are mounted.

As indicated by an arrow Y1, the control IC 40 receives an RF signal outputted from a radio frequency integrated circuit (RFIC) (not illustrated). The control IC 40 outputs a control signal to the signal line S1. The signal line S1 is connected to the flexible substrate 1. Further, the control IC 40 outputs an RF signal to the signal line S2. The signal line S2 is connected to the power amplifier IC 41. The output signal of the power amplifier IC 41 is outputted to the signal line S3.

As indicated by an arrow Y2, the antenna switch 42 inputs and outputs an RF signal to and from an antenna (not illustrated). The signal lines S4 and S5 are connected to the antenna switch 42. The signal line S4 is connected to the low-noise amplifier IC 43. The signal line S5 is connected to the flexible substrate 1.

The power amplifier IC 41 outputs an RF signal from an antenna (not illustrated) via the signal line S3 and the antenna switch 42. The low-noise amplifier IC 43 receives an RF signal from an antenna (not illustrated) via the antenna switch 42 and the signal line S4. As indicated by the arrow Y2, the low-noise amplifier IC 43 outputs an RF signal to an RFIC (not illustrated).

The electronic components 20-1 to 20-12 are, for example, filter circuit(s), resistor(s), capacitor(s), and/or the like. The electronic components 20-1 to 20-12 are mounted on the surface of the multilayer wiring board 101.

The flexible substrate 1 is mounted on the main surface of the multilayer wiring board 101. The flexible substrate 1 includes a long portion 1L and short portions 1S1 and 1S2. The short portion 1S1, which is one end portion of the flexible substrate 1, and the short portion 1S2, which is the other end portion of the flexible substrate 1, are connected to different positions of the multilayer wiring board 101. The flexible substrate 1 electrically connects the signal line S1 and the signal line S5 of the multilayer wiring board 101. The structure and the like of the flexible substrate 1 will be described later.

### Multilayer Wiring Board

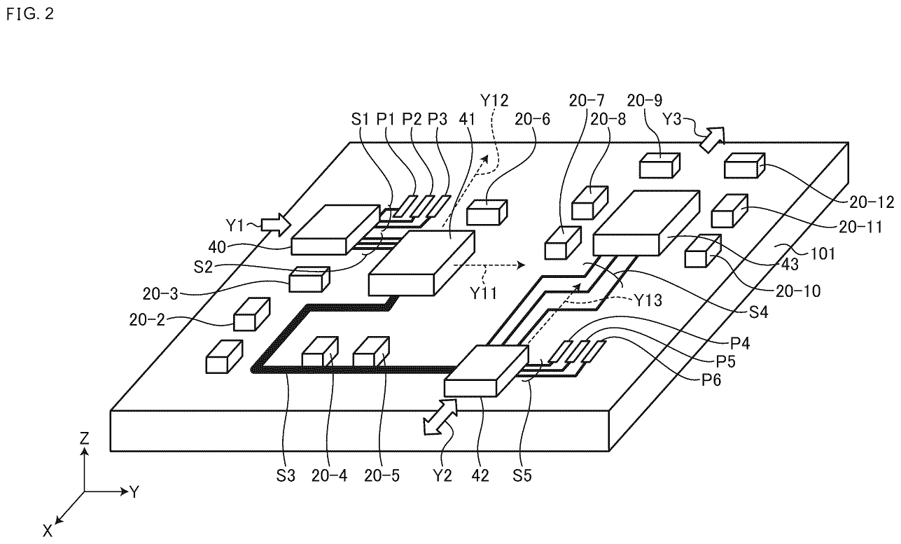

FIG. 2 is a perspective view illustrating a configuration of the multilayer wiring board 101 before the flexible substrate 1 is mounted in FIG. 1. Referring to FIG. 2, electrodes P1 to P6 for mounting the flexible substrate 1 are provided on the surface of the multilayer wiring board 101. The electrodes P1 to P3 are electrodes for connecting the short portion 1S1 (see FIG. 1) of the flexible substrate 1. The electrodes P4 to P6 are electrodes for connecting the short portion 1S2 (see FIG. 1) of the flexible substrate 1.

When the flexible substrate 1 illustrated in FIG. 1 is not provided, electromagnetic waves may leak from the power amplifier IC 41 and the antenna switch 42, as indicated by broken arrows Y11, Y12, and Y13 in FIG. 2, so as to have an effect on other circuit(s). Hereinafter, such an effect will be referred to as “signal interference”.

### Flexible Substrate

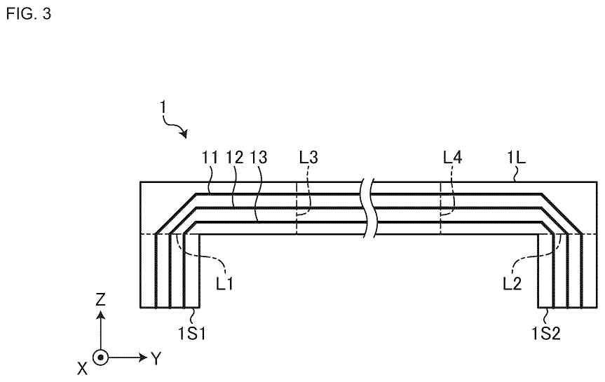

FIG. 3 is a view illustrating a configuration of the flexible substrate 1 according to the first embodiment. As illustrated in FIG. 3, the flexible substrate 1 has a thickness in the X-axis direction, and includes the long portion 1L extending in the Y-axis direction and the short portions 1S1 and 1S2 extending in the Z-axis direction. The short portion 1S1 is connected to one end portion of the long portion 1L. The short portion 1S2 is connected to the other end portion of the long portion 1L.

The flexible substrate 1 has a plurality of wiring lines 11, 12, and 13. The wiring lines 11, 12, and 13 are wiring lines for transmitting signals. In a state in which the flexible substrate 1 is mounted on the multilayer wiring board 101, the wiring lines 11, 12, and 13 transmit different signals. The wiring lines 11, 12, and 13 transmit the signals from the short portion 1S1 through the long portion 1L to the short portion 1S2. Since the signals are transmitted by the flexible substrate 1, the number of signal lines passing through the inside of the multilayer wiring board 101 can be reduced.

Further, the flexible substrate 1 has predetermined bending lines L1, L2, L3, and L4. The bending line L1 is provided at a boundary between the long portion 1L and the short portion 1S1. The bending line L2 is provided at a boundary between the long portion 1L and the short portion 1S2.

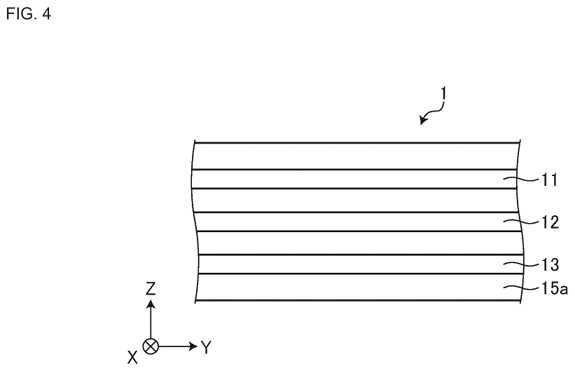

FIG. 4 is an enlarged view illustrating a portion of the flexible substrate 1 illustrated in FIG. 3. FIG. 4 is a view illustrating the structure of the long portion 1L of the flexible substrate 1. FIG. 4 is a view of the long portion 1L of the flexible substrate 1 in FIG. 3 when viewed from the negative direction of the X-axis.

As illustrated in FIG. 4, the flexible substrate 1 includes the wiring lines 11, 12, and 13 and a coverlay 15a covering the wiring lines 11, 12, and 13. The wiring lines 11, 12, and 13 are formed of, for example, copper foil. The wiring lines 11, 12, and 13 are covered by the coverlay 15a in a state in which the wiring lines 11, 12, and 13 do not cross each other. Therefore, the wiring lines 11, 12, and 13 are not electrically conductive to each other.

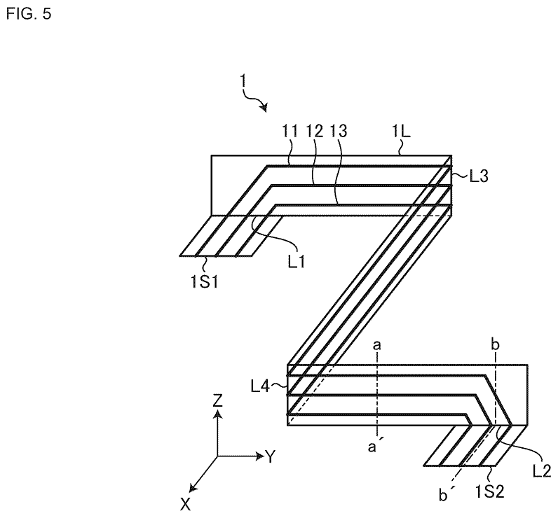

FIG. 5 is a view illustrating the flexible substrate 1 in a state of being bent along the bending lines L1, L2, L3, and L4. The flexible substrate 1 illustrated in FIG. 3 becomes the state of the flexible substrate 1 illustrated in FIG. 5 by being bent in a manner described below. Specifically, on the bending line L1 in FIG. 3, the flexible substrate 1 is bent so that the long portion 1L and the short portion 1S1 form an angle of substantially 90 degrees. Also, on the bending line L2 in FIG. 3, the flexible substrate 1 is bent so that the long portion 1L and the short portion 1S2 form an angle of substantially 90 degrees. Further, on the bending line L3 in FIG. 3, the flexible substrate 1 is bent so that in the long portion 1L, a portion connected to the short portion 1S1 and the other portion form an angle of substantially 90 degrees. Further, on the bending line L4 in FIG. 3, the flexible substrate 1 is bent so that in the long portion 1L, a portion connected to the short portion 1S2 and the other portion form an angle of substantially 90 degrees. By bending the flexible substrate 1 along the bending lines L1, L2, L3, and L4 in the manner described above, the flexible substrate 1 in the state illustrated in FIG. 5 is obtained. The flexible substrate 1 in the bent state is mounted on the multilayer wiring board 101.

In the flexible substrate 1 in the state illustrated in FIG. 5, a portion bent so as to extend in a direction away from the multilayer wiring board 101 is the long portion 1L. The long portion 1L is erected from the main surface of the multilayer wiring board 101 by being bent along the predetermined bending lines. The long portion 1L corresponds to an erected portion of the present disclosure.

In the flexible substrate 1 in the state illustrated in FIG. 5, the portions bent so as to extend along the multilayer wiring board 101 are the short portions 1S1 and 1S2. The short portions 1S1 and 1S2 are connected to the main surface of the multilayer wiring board 101. The short portions 1S1 and 1S2 correspond to connection portions of the present disclosure.

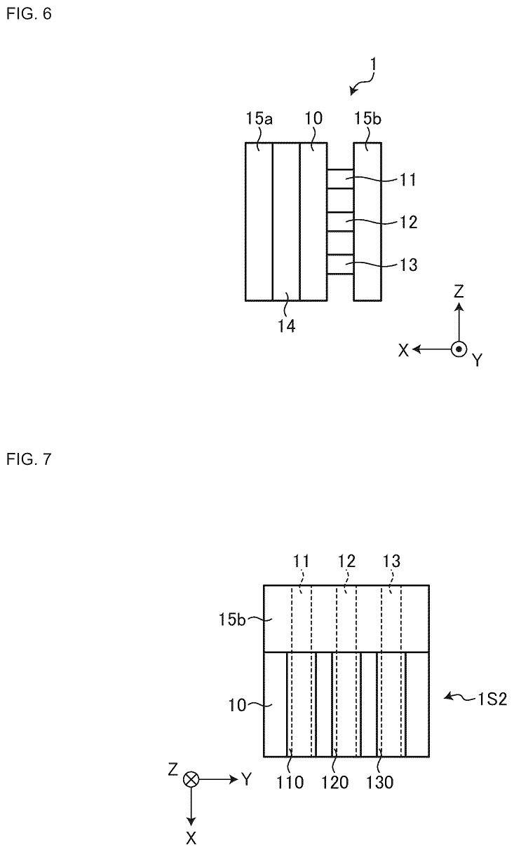

FIG. 6 is a view illustrating a cross-section of a portion of the flexible substrate 1 illustrated in FIG. 5. FIG. 6 is a view illustrating a cross-section of a portion taken along line a-a′ in FIG. 5 when viewed from the positive direction of the Y-axis.

Referring to FIG. 6, the flexible substrate 1 includes a base film 10, a ground layer 14, the wiring lines 11, 12, and 13, and coverlays 15a and 15b. The ground layer 14 is formed on one main surface of the base film 10, and the wiring lines 11, 12, and 13 are formed on the other main surface of the base film 10. Since the base film 10 is present, the ground layer 14 is not in electrical contact with the wiring line 11, 12, or 13. The ground layer 14 is electrically connected to a reference potential of the multilayer wiring board 101. The reference potential is, for example, the ground potential. The ground layer 14 corresponds to a first ground layer of the present disclosure.

The ground layer 14 is formed of, for example, copper foil. The wiring lines 11, 12, and 13 are formed of, for example, copper foil. In FIG. 6, air gaps are drawn between the wiring lines 11, 12, and 13 for convenience of drawing. Such air gaps do not actually exist. The wiring lines 11, 12, and 13 are covered by the coverlay 15b in a state in which the wiring lines 11, 12, and 13 do not cross each other. Therefore, the wiring lines 11, 12, and 13 are not electrically conductive to each other.

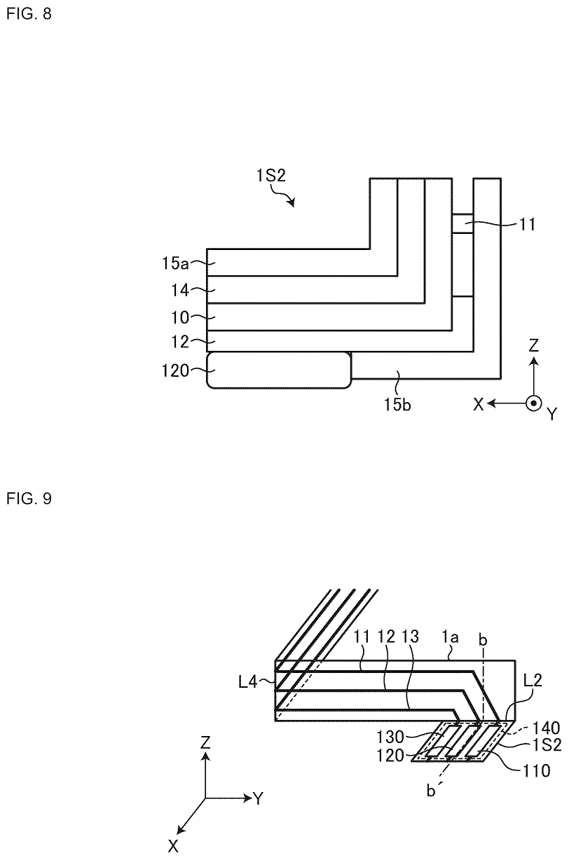

FIGS. 7 and 8 are views for explaining the structure of the short portion 1S2 of the flexible substrate 1 illustrated in FIG. 5. FIG. 7 is a view of the short portion 1S2 in FIG. 5 when viewed from the negative direction of the Z-axis. FIG. 8 is a view illustrating a cross-section of a portion taken along line b-b′ in FIG. 5 when viewed from the Y-axis direction.

In FIGS. 7 and 8, the wiring lines 11, 12, and 13 are provided on the negative side of the Z-axis of the base film 10. Since FIG. 8 illustrates a cross-section taken along line b-b′ in FIG. 5, the wiring lines 11 and 13 are not drawn while the wiring line 12 is drawn. A portion of the wiring line 12 on the negative side of the Z-axis is provided with solder plating 120. Similarly, a portion of the wiring line 11 on the negative side of the Z-axis is provided with solder plating 110, and a portion of the wiring line 13 in the negative direction of the Z-axis is provided with solder plating 130.

The portion of the wiring line 12 not provided with the solder plating 120 is covered with the coverlay 15b. Similarly, the portion of the wiring line 11 not provided with the solder plating 110 and the portion of the wiring line 13 not provided with the solder plating 130 are covered with the coverlay 15b. In FIG. 8, an air gap is drawn between the wiring line 11 and the wiring line 12 for convenience of drawing. Such an air gap does not actually exist.

In FIG. 8, the ground layer 14 is provided on the positive side of the Z-axis of the base film 10. The positive side of the Z-axis of the ground layer 14 is covered with the coverlay 15a.

Returning to FIG. 1, focusing on the flexible substrate 1, a plurality of components are mounted on the main surface of the multilayer wiring board 101. When viewing the main surface of the multilayer wiring board 101 in plan, the flexible substrate 1 is mounted on the multilayer wiring board 101, passing between the plurality of components mounted on the multilayer wiring board 101, to electrically connect the signal line S1 and the signal line S5. In other words, the flexible substrate 1 electrically connects the electrodes at two positions separated from each other on the main surface of the multilayer wiring board 101. That is, the flexible substrate 1 has the short portions 1S1 and 1S2 corresponding to two connection portions, and the short portions 1S1 and 1S2 are connected to separate positions on the main surface of the multilayer wiring board 101. At this time, the flexible substrate 1 is provided so that the side surface of the long portion 1L extends along the main surface of the multilayer wiring board 101. The flexible substrate 1 is mounted so as to pass through a portion where no component is provided, avoiding components on the main surface of the multilayer wiring board 101. Since the flexible substrate 1 has the ground layer 14, the function of an electromagnetic shield can be realized, so that the signal interference can be suppressed.

### (Effects)

According to the first embodiment described above, since the flexible substrate 1 having the ground layer is provided between the components, the function of an electromagnetic shield can be realized, so that the signal interference can be suppressed.

### Second Embodiment

### Configuration

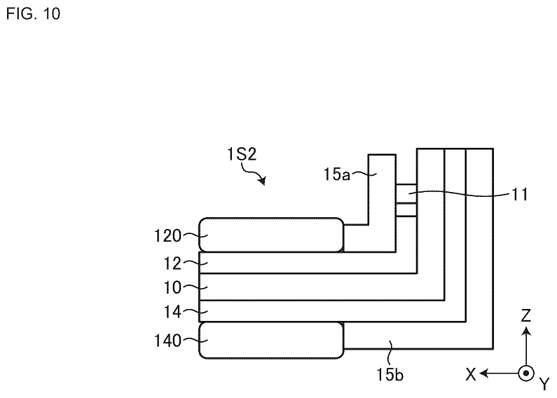

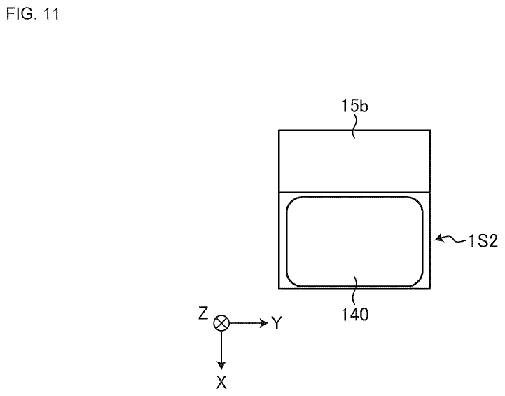

FIGS. 9, 10 and 11 are views illustrating a configuration of a main portion of a flexible substrate 1a used in an electronic component module according to a second embodiment. FIG. 10 is a view illustrating a cross-section of a portion taken along line b-b′ in FIG. 9 when viewed from the Y-axis direction. FIG. 11 is a view of a short portion 1S2 of the flexible substrate 1a when viewed from the negative direction of the Z-axis.

The flexible substrate 1a illustrated in FIGS. 9 to 11 differs from the flexible substrate 1 of the first embodiment described with reference to FIGS. 3 to 8 in the arrangement of the ground layer 14. Referring to FIG. 9, wiring lines 11, 12, and 13 are exposed to a surface of the short portion 1S2 on the positive side of the Z-axis. A ground layer 14 is provided on the negative side of the Z-axis of the wiring lines 11, 12, and 13.

Referring to FIG. 10, in the short portion 1S2, the wiring line 12 is provided on the positive side of the Z-axis of the base film 10. The portions of the wiring line 11, the wiring line 12, and the wiring line 13 (see FIG. 9) where no solder plating is provided are covered with a coverlay 15a. Solder plating 120 is provided on the positive side of the Z-axis of the wiring line 12. An air gap is drawn between the wiring line 12 and the wiring line 11 for convenience of drawing. Such an air gap does not actually exist.

The ground layer 14 is provided on the negative side of the Z-axis of the base film 10. Solder plating 140 is provided on the negative side of the Z-axis of the ground layer 14. Referring to FIG. 11, the solder plating 140 is provided on the negative side of the Z-axis of the short portion 1S2, and a coverlay 15b is provided on the negative side of the X-axis of the solder plating 140. The ground layer 14 and the ground electrode on the surface of the multilayer wiring board 101 are electrically connected by the solder plating 140. Note that a short portion 1S1 (not illustrated) on the opposite side of the flexible substrate 1a has the same structure as the short portion 1S2.

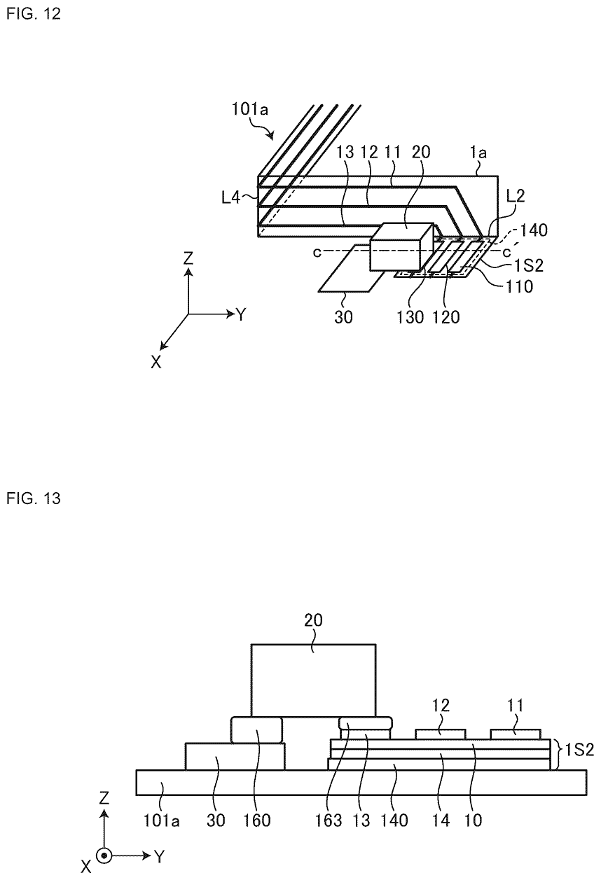

FIG. 12 is a view illustrating a first example of a structure in which a surface mount device (SMD) is mounted using the flexible substrate 1a according to the second embodiment. FIG. 12 is a view illustrating an example in which an electronic component 20 is connected to the wiring line 13 illustrated in FIG. 9. A multilayer wiring board 101a in the present example has a land pattern 30.

When the land pattern 30 is provided on the multilayer wiring board 101a, the electronic component 20, which is the surface mount device, is provided on the flexible substrate 1a so as to bridge the land pattern 30 and the wiring line 13. At this time, an electrode (not illustrated) of the electronic component 20 is connected to the wiring line 13, and another electrode (not illustrated) of the electronic component 20 is connected to the land pattern 30. In other words, a portion of the wiring line 13 is provided in the short portion 1S2, and the electronic component 20 is connected to the wiring line 13 provided in the short portion 1S2.

FIG. 13 is a view illustrating a cross-section of a portion of the flexible substrate 1a illustrated in FIG. 12. FIG. 13 is a view illustrating a cross-section of a portion taken along line c-c′ in FIG. 12 when viewed from the positive direction of the X-axis.

Referring to FIGS. 12 and 13, the short portion 1S2 of the flexible substrate 1a is connected to the multilayer wiring board 101a by the solder plating 140. The electronic component 20 is connected to the wiring line 13 of the short portion 1S2 by solder plating 163. The electronic component 20 is connected to the land pattern 30 of the flexible substrate 1a by being soldered with solder plating 160. Even when the positions of the wiring lines 11, 12, and 13 and the position of the ground layer 14 are opposite to those of the first embodiment, since the flexible substrate 1a has the ground layer 14, the function of an electromagnetic shield can be realized, so that the signal interference can be suppressed.

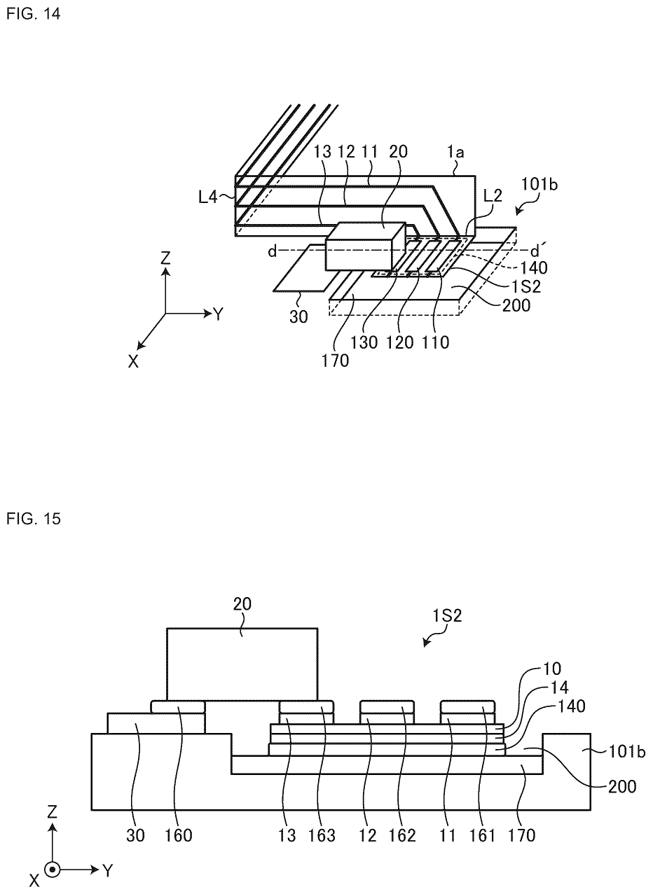

FIG. 14 is a view illustrating a second example of a structure in which a surface mount device is mounted using the flexible substrate 1a according to the second embodiment. A multilayer wiring board 101b in the present example has a recess 200. The recess 200 is a portion recessed in the negative direction of the Z-axis from the position of the land pattern 30 of the multilayer wiring board 101b. The short portion 1S2 is provided in the recess 200. A ground layer 170 is provided between the short portion 1S2 and the bottom of the recess 200.

FIG. 15 is a view illustrating a cross-section of a portion of the flexible substrate 1a illustrated in FIG. 14. FIG. 14 is a view illustrating a cross-section of a portion taken along line d-d′ in FIG. 12 when viewed from the positive direction of the X-axis. The ground layer 170 is provided to align the position of the land pattern 30 in the Z-axis direction with the position of the wiring line 13 in the Z-axis direction. In other words, the ground layer 170 is provided to adjust the height in the Z-axis direction between the land pattern 30 and the wiring line 13.

Referring to FIGS. 14 and 15, the ground layer 14 of the short portion 1S2 of the flexible substrate 1a is connected to the ground layer 170 of the multilayer wiring board 101a by the solder plating 140. In the short portion 1S2, the wiring line 11 is provided with solder plating 161, the wiring line 12 is provided with solder plating 162, and the wiring line 13 is provided with the solder plating 163.

The wiring line 13 of the short portion 1S2 is connected to the electronic component 20 by the solder plating 163. The electronic component 20 is connected to the land pattern 30 of the flexible substrate 1a by the solder plating 160.

Even when the positions of the wiring lines 11, 12, and 13 and the position of the ground layer 14 are opposite to those of the first embodiment, since the flexible substrate 1a has the ground layer 14, the function of an electromagnetic shield can be realized, so that the signal interference can be suppressed.

### Modification of Second Embodiment

In the flexible substrate 1a illustrated in FIGS. 9 to 11, the ground layer 14 is provided on one side of the base film 10. The ground layer 14 may alternatively be provided on both sides of the base film.

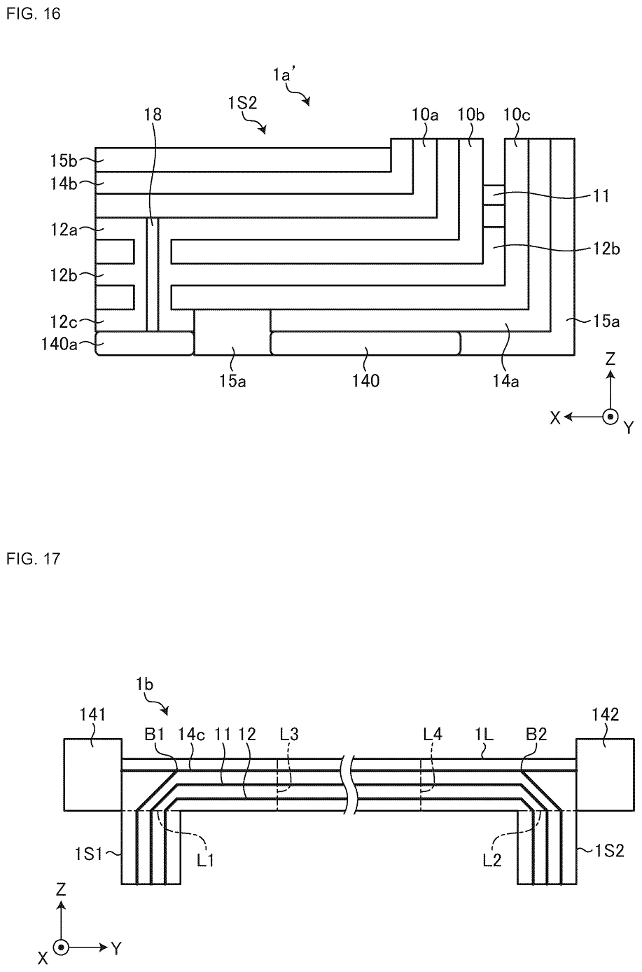

FIG. 16 is a sectional view illustrating a configuration of a flexible substrate 1a′ according to a modification of the second embodiment. FIG. 16 is a view illustrating a cross-section of a portion of the flexible substrate 1a′ corresponding to the line b-b′ in FIG. 9 when viewed from the positive direction of the Y-axis.

As illustrated in FIG. 16, the flexible substrate 1a′ includes three layers of base films 10a, 10b, and 10c, ground layers 14a and 14b, wiring lines 11, 12a, 12b, and 12c, coverlays 15a and 15b, and a via hole 18. The ground layer 14a corresponds to a first ground layer of the present disclosure. The ground layer 14b corresponds to a second ground layer of the present disclosure.

The base films 10a, 10b, and 10c and the wiring lines 12a, 12b, and 12c are alternately laminated in the Z-axis direction. The via hole 18 is formed through the wiring lines 12a, 12b, and 12c. Therefore, the wiring lines 12a, 12b, and 12c are electrically connected by the via hole 18. Solder plating 140a is provided on the negative side of the Z-axis of the wiring line 12c.

The ground layer 14b and the coverlay 15b are provided on the positive side of the Z-axis of the base film 10a. The ground layer 14a and the coverlay 15a are provided on the negative side of the Z-axis of the base film 10c. Solder plating 140 is provided on the negative side of the Z-axis of the ground layer 14a, and the coverlay 15a is provided on the negative side of the X-axis of the solder plating 140. The ground layer 14a and a ground electrode (not illustrated) on the surface of the multilayer wiring board are electrically connected by the solder plating 140. An air gap is drawn between the wiring line 12b and the wiring line 11 for convenience of drawing. Such an air gap does not actually exist.

In the configuration illustrated in FIG. 16, focusing on the wiring lines 12a and 12b, the ground layer 14b is provided on the positive side of the Z-axis of the wiring lines 12a and 12b, and the ground layer 14a is provided on the negative side of the Z-axis of the wiring lines 12a and 12b. The wiring lines 12a and 12b are provided between the ground layer 14a and the ground layer 14b, and the wiring lines 12a and 12b are sandwiched by the ground layers 14a and 14b. Therefore, the function of an electromagnetic shield by the ground layers 14a and 14b is realized, so that when the wiring lines 12a and 12b transmit a radio frequency signal, the signal interference to other circuits can be suppressed.

### Effects

According to the second embodiment and its modification described above, by providing the flexible substrate having the ground layer 14 between the components, the function of an electromagnetic shield can be realized, so that the signal interference can be suppressed.

### Third Embodiment

### Configuration

FIG. 17 is a view illustrating a configuration of a main portion of a flexible substrate 1b used in an electronic component module according to a third embodiment. The flexible substrate 1b illustrated in FIG. 17 differs from the flexible substrate 1 illustrated in FIG. 3 in that an electrode plate 141 is provided at one end of the long portion 1L, an electrode plate 142 is provided at the other end of the long portion 1L, and a ground line 14c is provided.

One end of the ground line 14c is connected to a short portion 1S1. The ground line 14c is branched at a branch point B1 to be electrically connected to the electrode plate 141. The other end of the ground line 14c is connected to a short portion 1S2. The ground line 14c is branched at a branch point B2 to be electrically connected to the electrode plate 142.

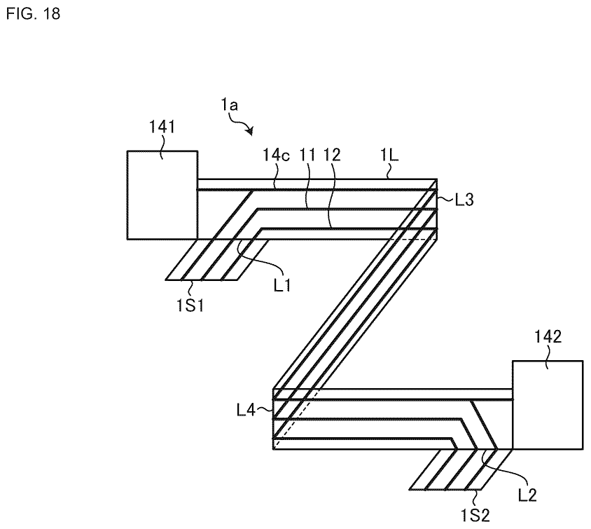

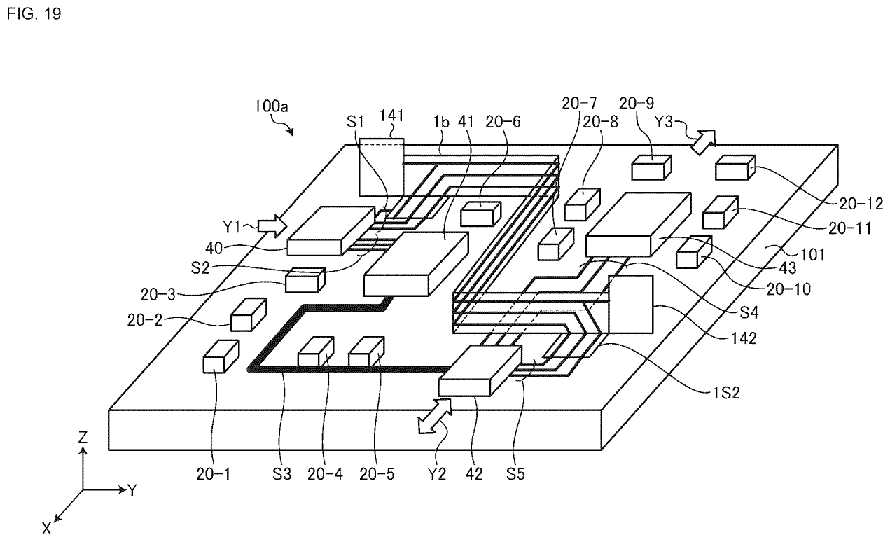

Similar to the flexible substrate 1 illustrated in FIG. 3, the flexible substrate 1b has bending lines L1, L2, L3, and L4. The flexible substrate 1b in the state illustrated in FIG. 18 is obtained by being bent along the respective bending lines L1, L2, L3, and L4 in the same manner as the flexible substrate 1 illustrated in FIG. 3. FIG. 18 is a view illustrating the flexible substrate 1b in the state of being bent along the respective bending lines L1, L2, L3, and L4. An electronic component module 100a illustrated in FIG. 19 is obtained by mounting the flexible substrate 1b in the bent state on the multilayer wiring board 101 described with reference to FIG. 2.

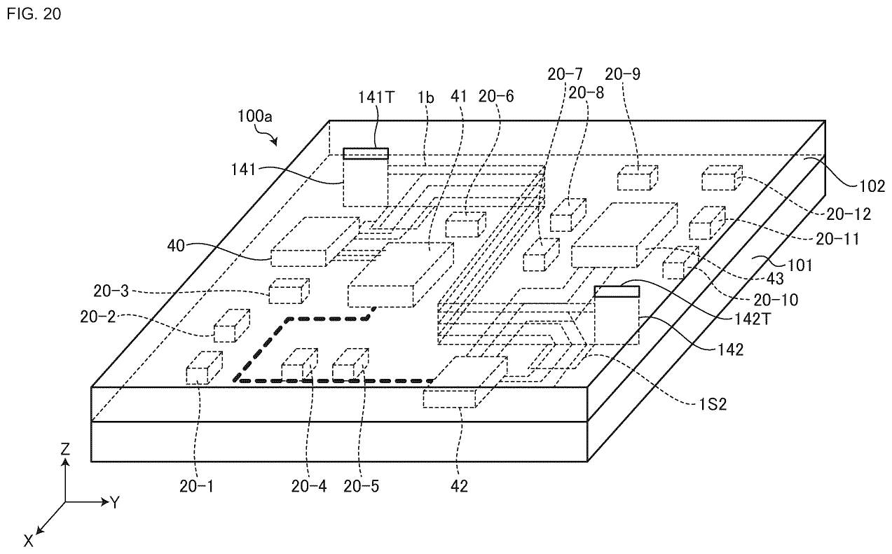

FIG. 19 is a perspective view illustrating the electronic component module 100a according to the third embodiment. Referring to FIG. 19, the electrode plates 141 and 142 of the flexible substrate 1b extend in the positive direction of the Z-axis. FIG. 20 is a view illustrating a state in which the electronic component module 100a is filled with a resin 102. FIG. 20 illustrates a state in which the electronic component module 100a is filled with the resin 102 on the upper side of the multilayer wiring board 101, i.e., in the positive direction of the Z-axis of the multilayer wiring board 101. The resin 102 is an insulating member. The position of the flexible substrate 1b can be fixed by filling the resin 102. At this time, since the resin 102 is filled, the portion of the flexible substrate 1b other than end portions of the electrode plates and the multilayer wiring board 101a are sealed by the resin 102, which is an insulating member.

As illustrated in FIG. 20, in the state in which the resin 102 is filled, a tip 141T of the electrode plate 141 in the positive direction of the Z-axis and a tip 142T of the electrode plate 142 in the positive direction of the Z-axis are exposed without being covered by the resin 102. After filling the resin 102, the surface of the resin 102 in the Z-axis direction is polished and flattened as necessary, so that the amount of exposure of the tips 141T and 142T can be adjusted. Further, by providing a metal layer (not illustrated) on the surface of the resin 102 in the Z-axis direction, the metal layer and the tips 141T and 142T may be electrically connected. The metal layer can be formed by a sputtering method or by means of vapor deposition. When a ground potential is applied to the metal layer, the ground potential is applied to the end portion of the electrode plate, i.e., to the tips 141T and 142T. With the flexible substrate 1b having the ground potential, the function of an electromagnetic shield can be realized, so that the signal interference can be suppressed.

### Effects

According to the third embodiment described above, in the electronic component module 100a, by providing the flexible substrate 1b having the ground layer between the components, the function of an electromagnetic shield can be realized, so that the signal interference can be suppressed.

### Fourth Embodiment

### Configuration

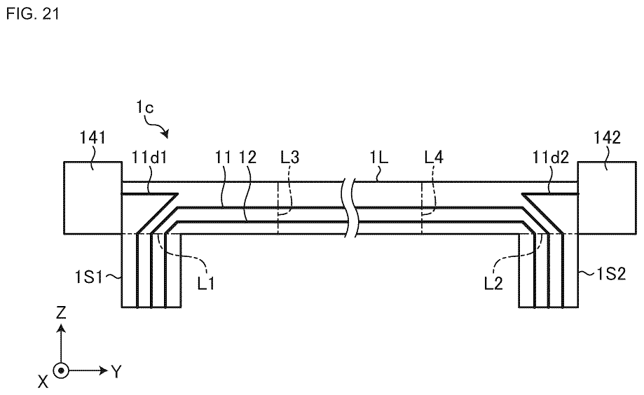

FIG. 21 is a view illustrating a configuration of a main portion of a flexible substrate 1c used in an electronic component module according to a fourth embodiment. The flexible substrate 1c illustrated in FIG. 21 differs from the flexible substrate 1 illustrated in FIG. 3 in that it has wiring lines 11d1 and 11d2 instead of the wiring line 11 illustrated in FIG. 3. One end of the wiring line 11d1 is connected to a short portion 1S1. The other end of the wiring line 11d1 is electrically connected to an electrode plate 141. One end of the wiring line 11d2 is connected to a short portion 1S2. The other end of the wiring line 11d2 is electrically connected to an electrode plate 142. The electrode plates 141 and 142 correspond to a first electrode plate of the present disclosure.

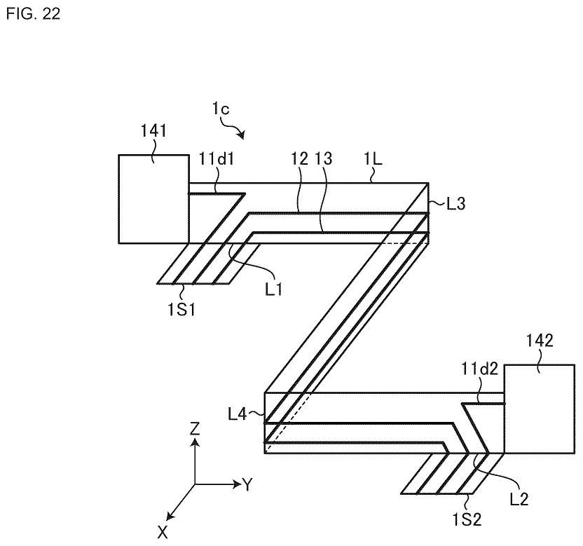

Similar to the flexible substrate 1 illustrated in FIG. 3, the flexible substrate 1b has bending lines L1, L2, L3, and L4. The flexible substrate 1c in the state illustrated in FIG. 22 is obtained by being bent along the respective bending lines L1, L2, L3, and L4 in the same manner as the flexible substrate 1 illustrated in FIG. 3. FIG. 22 is a view illustrating the flexible substrate 1c in a state of being bent along the respective bending lines L1, L2, L3, and L4. The flexible substrate 1c in the bent state is mounted on the multilayer wiring board 101 described with reference to FIG. 2.

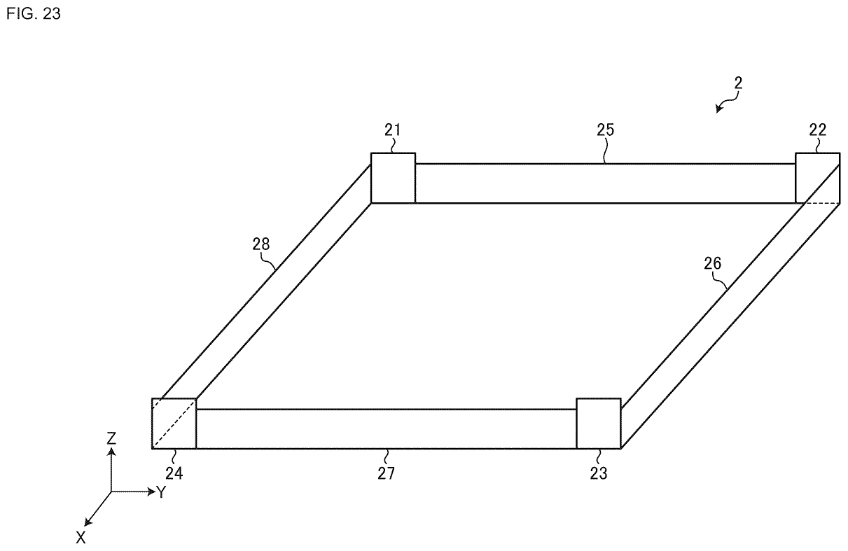

Further, in the present embodiment, a ground substrate 2 illustrated in FIG. 23 is used together with the flexible substrate 1c in the bent state. FIG. 23 is a perspective view illustrating a configuration example of the ground substrate. The ground substrate 2 illustrated in FIG. 23 is provided so as to surround the periphery of the flexible substrate 1c in the bent state. The ground substrate 2 has electrode plates 21, 22, 23, and 24, and long portions 25, 26, 27, and 28. The electrode plates 21, 22, 23, and 24 correspond to a second electrode plate of the present disclosure.

The ground substrate 2 has a rectangular shape when viewed from the positive direction of the Z-axis. The electrode plates 21, 22, 23, and 24 are provided at positions corresponding to four corners of the rectangular shape of the ground substrate 2. The long portion 25 is provided between the electrode plate 21 and the electrode plate 22. The long portion 26 is provided between the electrode plate 22 and the electrode plate 23. The long portion 27 is provided between the electrode plate 23 and the electrode plate 24. The long portion 28 is provided between the electrode plate 24 and the electrode plate 21.

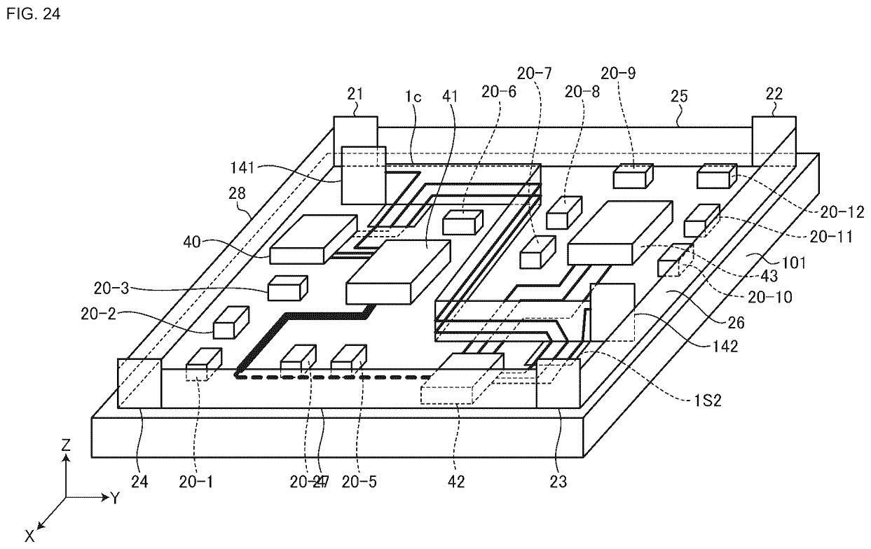

The state illustrated in FIG. 24 is obtained by providing the flexible substrate 1c in the bent state illustrated in FIG. 22 and the ground substrate 2 illustrated in FIG. 23 on the multilayer wiring board 101 illustrated in FIG. 2. FIG. 24 is a view illustrating a state in which the flexible substrate 1c and the ground substrate 2 are provided on the multilayer wiring board 101. The flexible substrate 1c and the ground substrate 2 are provided on a surface of the multilayer wiring board 101 in the positive direction of the Z-axis. The flexible substrate 1c and the ground substrate 2 are connected to electrodes or pads on the surface of the multilayer wiring board 101 by soldering. Further, in the state illustrated in FIG. 24, the positions of the flexible substrate 1c and the ground substrate 2 can be fixed by filling a resin.

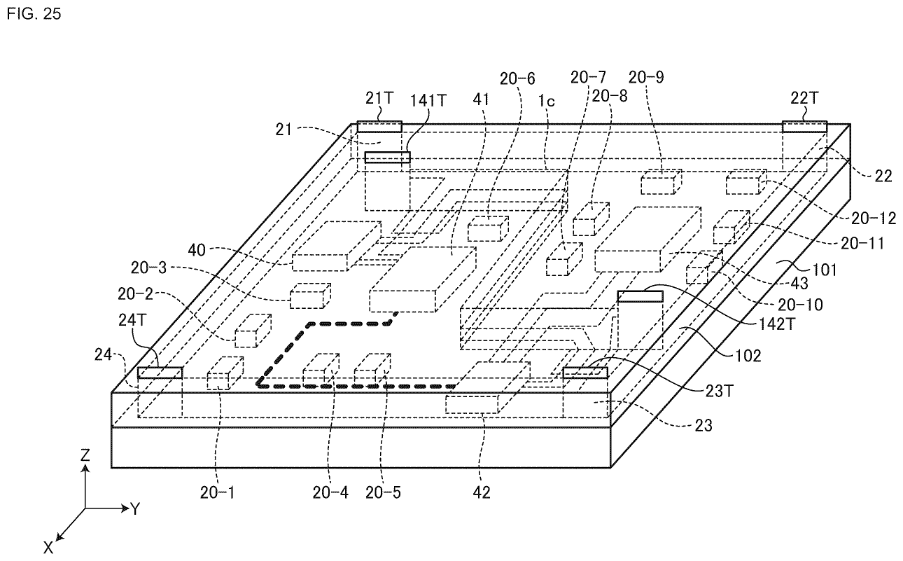

FIG. 25 is a view illustrating a state in which a resin 102 is filled in the state illustrated in FIG. 24. As illustrated in FIG. 25, in the state in which the resin 102 is filled, the tip 141T of the electrode plate 141 in the positive direction of the Z-axis, the tip 142T of the electrode plate 142 in the positive direction of the Z-axis, a tip 21T of the electrode plate 21 in the positive direction of the Z-axis, a tip 22T of the electrode plate 22 in the positive direction of the Z-axis, a tip 23T of the electrode plate 23 in the positive direction of the Z-axis, and a tip 24T of the electrode plate 24 in the positive direction of the Z-axis are exposed without being covered by the resin 102. After filling the resin 102, a surface of the resin 102 in the Z-axis direction is polished and flattened as necessary, so that the amount of exposure of the tips 141T, 142T, 21T, 22T, 23T, and 24T can be adjusted.

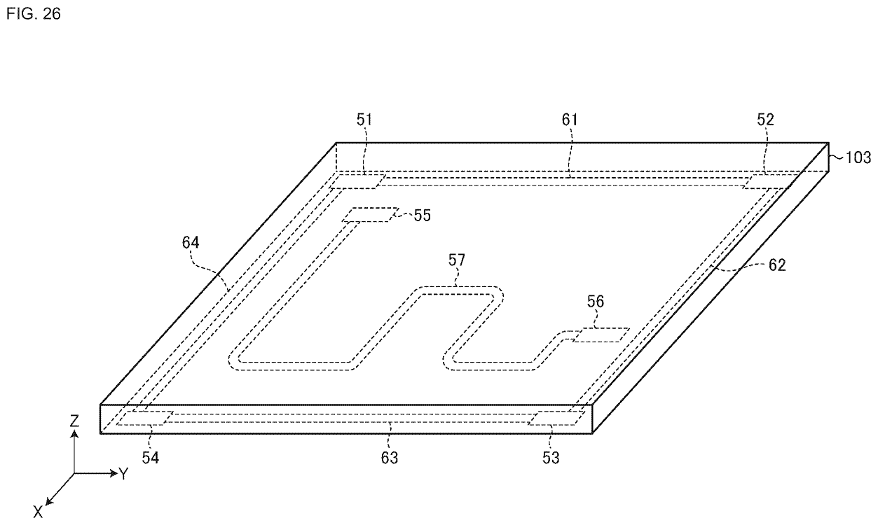

Further, a substrate may be added to electrically connect the tips 141T and 142T and to electrically connect the tips 21T, 22T, 23T, and 24T. FIG. 26 is a view illustrating an example of a connection substrate 103. FIG. 26 illustrates an example of the connection substrate 103 for electrically connecting each tip in FIG. 25. The connection substrate 103 corresponds to a connection substrate of the present disclosure.

In FIG. 26, electrodes 51, 52, 53, and 54 and wiring lines 61, 62, 63, and 64 are provided on a lower surface of the connection substrate 103, i.e., a surface of the connection substrate 103 on the negative side of the Z-axis. The electrodes 51, 52, 53, and 54 are provided at positions corresponding to the tips 21T, 22T, 23T, and 24T (see FIG. 25). Therefore, the electrode 51 of the connection substrate 103 is connected to the tip 21T (see FIG. 25). The electrode 52 of the connection substrate 103 is connected to the tip 22T (see FIG. 25). The electrode 53 of the connection substrate 103 is connected to the tip 23T (see FIG. 25). The electrode 54 of the connection substrate 103 is connected to the tip 24T (see FIG. 25). The wiring line 61 electrically connects the electrode 51 and the electrode 52. The wiring line 62 electrically connects the electrode 52 and the electrode 53. The wiring line 63 electrically connects the electrode 53 and the electrode 54. The wiring line 64 electrically connects the electrode 54 and the electrode 51.

An electrode 55, an electrode 56, and a wiring line 57 are provided on the lower surface of the connection substrate 103 in FIG. 26. The electrodes 55 and 56 are provided at positions corresponding to the tips 141T and 142T (see FIG. 25). Therefore, the electrode 55 of the connection substrate 103 is connected to the tip 141T (see FIG. 25). The electrode 56 of the connection substrate 103 is connected to the tip 142T (see FIG. 25). The wiring line 57 electrically connects the electrode 55 and the electrode 56. In other words, the end portions of the respective electrode plates are connected to the electrodes at corresponding positions.

The connection substrate 103 illustrated in FIG. 26 is placed on an upper surface of the resin 102 illustrated in FIG. 25, i.e., a surface of the resin 102 on the positive side of the Z-axis, so that the tips 21T, 22T, 23T, 24T, 141T, and 142T are electrically connected to the respective electrodes 51, 52, 53, 54, 55, and 56. At this time, the flexible substrate 1c and the ground substrate 2 are covered by the connection substrate 103. Therefore, the wiring line 57 that transmits the radio frequency signal can be covered by, for example, the electrodes having the ground potential. Thus, the function of an electromagnetic shield can be realized, so that the signal interference can be suppressed.

### Effects

According to the fourth embodiment described above, in the electronic component module, by providing a flexible substrate having a ground layer between the components and covering the components with a substrate having a ground layer, the function of an electromagnetic shield can be realized, so that the signal interference can be suppressed.

What is claimed is:

1. An electronic component module comprising:
a rigid board;
a plurality of electronic components mounted on the rigid board; and
a flexible substrate that is bendable and mounted on the rigid board,
wherein
when viewing one main surface of the rigid board in plan, the flexible substrate is mounted on the rigid board, passing between the plurality of electronic components mounted on the rigid board,
the flexible substrate includes a wiring line configured to transmit a signal, and a first ground layer, and
the first ground layer is electrically connected to a reference potential of the rigid board.

2. The electronic component module according to claim 1, wherein
the flexible substrate includes a connection portion connected to the main surface of the rigid board, and an erected portion erected from the main surface of the rigid board by being bent, and
the flexible substrate in a bent state is mounted on the rigid board.

3. The electronic component module according to claim 2, wherein
the flexible substrate includes two of the connection portions, and
the two of the connection portions are connected to separate positions on the main surface of the rigid board.

4. The electronic component module according to claim 1, wherein
the flexible substrate includes a base film,
the wiring line is on one main surface side of the base film, and
the first ground layer is on another main surface side of the base film.

5. The electronic component module according to claim 1, wherein
the flexible substrate further includes a second ground layer, and
the wiring line is between the first ground layer and the second ground layer.

6. The electronic component module according to claim 2, wherein
a portion of the wiring line is in the connection portion, and
a surface mount device is connected to the wiring line in the connection portion.

7. The electronic component module according to claim 6, wherein
a recess is on the main surface of the rigid board, and
the connection portion is in the recess.

8. The electronic component module according to claim 2, wherein
the flexible substrate includes an electrode plate electrically connected to the first ground layer,
the electrode plate is erected from the main surface of the rigid board,
the rigid board and a portion of the flexible substrate other than an end portion of the electrode plate are sealed by an insulating member, and
the end portion of the electrode plate is configured to have a reference potential applied thereto.

9. The electronic component module according to claim 2, wherein
the flexible substrate includes a first electrode plate electrically connected to the wiring line,
the electronic component module further comprises:
a ground substrate which surrounds a periphery of the flexible substrate; and
a connection substrate that covers the flexible substrate and the ground substrate,
the ground substrate includes a second electrode plate,
the first electrode plate and the second electrode plate are erected from the main surface of the rigid board,
a portion of the flexible substrate other than an end portion of the first electrode plate, a portion of the ground substrate other than an end portion of the second electrode plate, and the rigid board are sealed by an insulating member,
the connection substrate includes electrodes at positions corresponding to the end portion of the first electrode plate and the end portion of the second electrode plate, and
the end portion of the first electrode plate and the end portion of the second electrode plate are connected to the electrodes at the positions corresponding thereto.

10. The electronic component module according to claim 2, wherein
the flexible substrate includes a base film,
the wiring line is on one main surface side of the base film, and
the first ground layer is on another main surface side of the base film.

11. The electronic component module according to claim 2, wherein
the flexible substrate further includes a second ground layer, and
the wiring line is between the first ground layer and the second ground layer.
